(19) United States
(12) Patent Application Publication
(10) Pub. No.: US 2025/0133760 A1
(43) Pub. Date: Apr. 24, 2025

(54) SEMICONDUCTOR DEVICE INCLUDING CONTACT ISOLATION LAYER AND METHOD FOR MANUFACTURING THE SAME

(71) Applicant: TAIWAN SEMICONDUCTOR MANUFACTURING COMPANY, LTD., Hsinchu (TW)

(72) Inventors: Ching-Pai Hsu, Hsinchu (TW); Chi-Ruei Yeh, Hsinchu (TW); Tsung-Yu Chiang, Hsinchu (TW)

(73) Assignee: TAIWAN SEMICONDUCTOR MANUFACTURING COMPANY, LTD., Hsinchu (TW)

(21) Appl. No.: 18/493,112

(22) Filed: Oct. 24, 2023

(51) Int. Cl. H01L 29/66; H01L 21/8238; H01L 27/092; H01L 29/06; H01L 29/423; H01L 29/775; H01L 29/78; H01L 29/786

(52) U.S. Cl. CPC H10D 30/024; H10D 30/014; H10D 30/43; H10D 30/6211; H10D 30/6735; H10D 30/6757; H10D 62/121; H10D 84/017; H10D 84/0186; H10D 84/038; H10D 84/85

(57) ABSTRACT

A method for manufacturing a semiconductor device includes: forming a dielectric layer on a semiconductor structure which includes a gate structure and a pair of source/drain features disposed at opposite sides of the gate structure; patterning the dielectric layer to form an opening which exposes a corresponding one of the source/drain features; conformally forming an isolation material layer to partially fill the opening, the isolation material layer including an upper portion disposed on a top surface of the patterned dielectric layer, a lower portion disposed on the corresponding one of the source/drain features, and an interconnecting portion connecting the upper portion and the lower portion; removing the upper and lower portions; and partially removing the interconnecting portion, such that the interconnecting portion has a thickness decreasing gradually in a direction from the top surface of the patterned dielectric layer to a bottom surface of the patterned dielectric layer.

### BACKGROUND

With rapid development of semiconductor technology, size of each electrical device (e.g., a transistor, a diode, or an inverter) in a semiconductor integrated circuit (IC) chip is becoming increasingly smaller, which is conducive to increasing a device functional density (i.e., the number of electrical devices per chip area) in the semiconductor IC chip. However, as the size of each electrical device in the semiconductor IC chip shrinks, some electrical issues may occur in the semiconductor IC chip, for example, an open circuit may be formed between a metal gate feature and an adjacent conductive feature. At present, the semiconductor industry strives to solve these electrical issues.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a method for manufacturing a semiconductor device in accordance with some embodiments.

FIGS. 2 to 9 are schematic views illustrating some intermediate stages of the method as depicted in FIG. 1 in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “over,” “top,” “bottom,” “upper.” “lower” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. It should be noted that the element(s) or feature(s) are exaggeratedly shown in the figures for the purposed of convenient illustration and are not in scale.

For the purposes of this specification and appended claims, unless otherwise indicated, all numbers expressing amounts, sizes, dimensions, proportions, shapes, formulations, parameters, percentages, quantities, characteristics, and other numerical values used in the specification and claims, are to be understood as being modified in all instances by the term “about” even though the term “about” may not expressly appear with the value, amount or range. Accordingly, unless indicated to the contrary, the numerical parameters set forth in the following specification and attached claims are not and need not be exact, but may be approximate and/or larger or smaller as desired, reflecting tolerances, conversion factors, rounding off, measurement error and the like, and other factors known to those of skill in the art depending on the desired properties sought to be obtained by the presently disclosed subject matter. For example, the term “about,” when referring to a value can be meant to encompass variations of, in some aspects±10%, in some aspects±5%, in some aspects±2.5%, in some aspects±1%, in some aspects±0.5%, and in some aspects±0.1% from the specified amount, as such variations are appropriate to perform the disclosed methods or employ the disclosed compositions.

With development of semiconductor technology, semiconductor integrated circuit (IC) chips have been applied in various fields. In recent years, application need for the semiconductor IC chips gradually increases, and in order to meet such application needs, an increased device functional density (i.e., the number of electrical devices per chip area) in a semiconductor IC chip is desired. In this case, a reduction in the size of each electrical device (for example, but not limited to, a transistor, a diode, an inverter, or other electrical devices) is required, so that a greater number of electrical devices can be included in the semiconductor IC chip. However, as the size of each electrical device in the semiconductor IC chip becomes smaller, some electrical issues or limitations on the device performance of each electrical device may occur. For example, a distance between a gate feature (e.g., a metal gate (MG)) and a conductive feature (e.g., a metal deposition (MD), i.e., a metal contact) adjacent to the gate feature may be reduced, and a size of an isolation feature that is disposed between the gate feature and the conductive feature and that is used to separate the gate feature and the conductive feature may be reduced, so that the gate feature may be in direct contact with the conductive feature, resulting in formation of an open circuit therebetween. For another example, it is difficult to lower a contact resistance between the conductive feature and a source/drain feature in contact with the conductive feature.

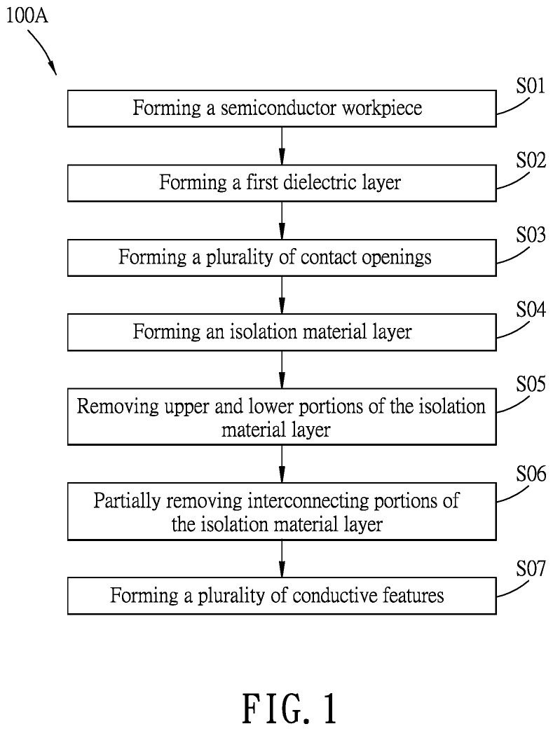

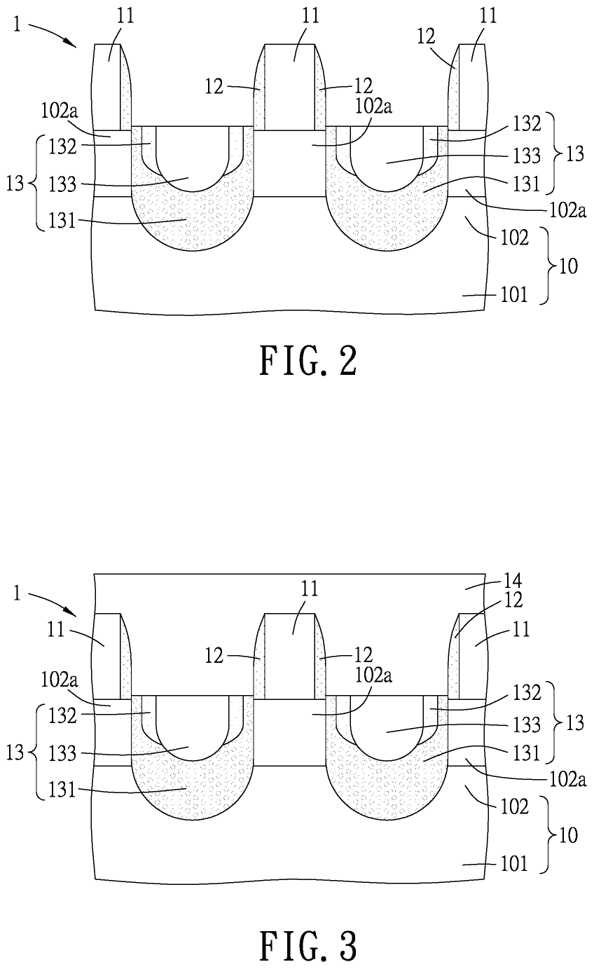

The present disclosure is directed to a semiconductor device including a contact isolation layer and a method for manufacturing the same. FIG. 1 is a flow diagram illustrating a method 100A for manufacturing a semiconductor device 200A shown in FIG. 9 in accordance with some embodiments. FIGS. 2 to 8 illustrate schematic views of some intermediate stages of the method 100A. Some portions may be omitted in FIGS. 2 to 8 for the sake of brevity. Additional steps can be provided before, after or during the method 100A, and some of the steps described herein may be replaced by other steps or be eliminated.

Referring to FIG. 1 and the example illustrated in FIG. 2, the method 100A begins at step S01, where a semiconductor workpiece 1 is formed. The semiconductor workpiece 1 includes a semiconductor substrate 10, a plurality of gate structures 11, a plurality of gate spacers 12, and a plurality of source/drain features 13. Source/drain region(s) may refer to a source or a drain, individually or collectively dependent upon the context.

The semiconductor substrate 10 may include, for example, but not limited to, an elemental semiconductor or a compound semiconductor. In some embodiments, the elemental semiconductor includes a single species of atoms, such as silicon (Si) or germanium (Ge) in column XIV of the periodic table, and may be in a crystal form, a polycrystalline form, or an amorphous form. Other suitable elemental semiconductor materials are within the contemplated scope of the present disclosure. In some embodiments, the compound semiconductor includes two or more elements, and examples thereof may include, silicon carbide (SiC), gallium arsenide (GaAs), gallium phosphide (GaP), indium phosphide (InP), indium arsenide (InAs), indium antimonide (InSb), silicon germanium (SiGe), gallium arsenide phosphide (GaAsP), aluminum indium arsenide (AlInAs), aluminum gallium arsenide (AlGaAs), gallium indium arsenide (GaInAs), gallium indium phosphide (GaInP), and gallium indium arsenide phosphide (GaInAsP). Other suitable compound semiconductor materials are within the contemplated scope of the present disclosure. The compound semiconductor may have a gradient feature in which the compositional ratio thereof changes from one location to another location therein. The compound semiconductor may be formed over a silicon substrate. The compound semiconductor may be strained. In some embodiments, the semiconductor substrate 10 may include a multilayer compound semiconductor structure. In some embodiments, the semiconductor substrate 10 may be a semiconductor on insulator (SOI) (e.g., silicon germanium on insulator (SGOI)). Generally, an SOI substrate includes a layer of a semiconductor material, such as epitaxial silicon (Si), germanium (Ge), silicon germanium (SiGe), or combinations thereof. The SOI substrate may be doped with a P-type dopant, for example, but not limited to, boron (Br), aluminum (Al), or gallium (Ga). Other suitable P-type dopant materials are within the contemplated scope of the present disclosure. Alternatively, the SOI substrate may be doped with an N-type dopant, for example, but not limited to, nitrogen (N), phosphorous (P), or arsenic (As). Other suitable N-type dopant materials are within the contemplated scope of the present disclosure. In some embodiments, the semiconductor substrate 10 may include a main portion 101, and a plurality of fin portions 102 that are disposed on the main portion 101 and that are spaced apart from one another (not shown). One of the fin portions 102 is shown in FIG. 2.

In some embodiments, the semiconductor device 200A to be manufactured is a fin field-effect transistor (FinFET) type semiconductor device. Each of the fin portions 102 is formed with a plurality of channel regions 102a. Each of the channel regions 102a is disposed below a corresponding one of the gate structures 11 and between two corresponding ones of the source/drain features 13. In some embodiments, the semiconductor device 200A to be manufactured may be a gate-all-around (GAA) transistor type semiconductor device or any other suitable FET type semiconductor device.

The gate structures 11 are disposed on the channel regions 102a, respectively. Each of the gate structures 11 may include a gate dielectric and a gate electrode.

In some embodiments, the gate dielectric may be made of a high-k dielectric material, for example, but not limited to, hafnium oxide, silicon nitride, silicon oxynitride, titanium oxide, hafnium zirconium oxide, tantalum oxide, hafnium silicon oxide, zirconium oxide, zirconium silicon oxide, lanthanum oxide, aluminum oxide, yttrium oxide, strontium titanate, barium titanate, barium zirconate, lanthanum silicon oxide, aluminum silicon oxide, hafnium lanthanum oxide, hafnium tantalum oxide, hafnium titanium oxide, other suitable high-k dielectric materials, or combinations thereof. Other suitable materials for the gate dielectric are within the contemplated scope of the present disclosure.

In some embodiments, the gate electrode may include polysilicon, metal (for example, but not limited to, aluminum (Al), tungsten (W), copper (Cu), other conductive metals, or combinations thereof) or a combination thereof. Other suitable materials for the gate electrode are within the contemplated scope of the present disclosure.

Each pair of the gate spacers 12 is disposed on a corresponding one of the channel regions 102a, and laterally covers a corresponding one of the gate structures 11. The gate spacers 12 may be formed by conformally depositing a spacer material layer (not shown) to cover the gate structures 11 and other structures, followed by conducting an etching process to etch a portion of the spacer material layer. The spacer material layer may be deposited by a suitable deposition process, for example, but not limited to, chemical vapor deposition (CVD), plasma-enhanced CVD (PECVD), atomic layer deposition (ALD), plasma-enhanced ALD (PEALD), or other suitable deposition processes. The spacer material layer may be made of a low-k dielectric material, for example, but not limited to, silicon oxide, silicon nitride, silicon carbide, silicon oxycarbide, silicon oxynitride, silicon carbonitride, silicon oxycarbonitride, or combinations thereof. Other suitable materials for forming the gate spacers 12 are within the contemplated scope of the present disclosure. In some embodiments, each of the gate spacers 12 may be formed as a multi-layered structure. For example, when each of the gate spacers 12 is formed as a two-layered structure, each of the gate spacers 12 may include an outer part and an inner part disposed between the outer part and a corresponding one of the gate structures 11. In some embodiments, the outer part and the inner part of the gate spacers 12 may be independently made of the low-k dielectric material. The etching process for forming the gate spacers 12 may be, for example, an anisotropic dry etching process or other suitable etching processes.

The source/drain features 13 may be formed in a plurality of source/drain recesses (not shown) which are formed by recessing a plurality of portions of a corresponding one of the fin portions 102 of the semiconductor substrate 10. In some embodiments, the corresponding one of the fin portions 102 of the semiconductor substrate 10 may be recessed using a suitable etching process, for example, but not limited to, an anisotropic dry etching process or other suitable etching processes, so as to form the source/drain recesses. The source/drain features 13 may be formed by one or more of epitaxial growth processes. The epitaxial growth process may be a selective epitaxial growth (SEG) process or other suitable epitaxial growth processes. In some embodiments, the source/drain features 13 are made of crystalline silicon. Other suitable semiconductor materials for forming the source/drain features 13 are within the contemplated scope of the present disclosure. In some embodiments, the source/drain features 13 (e.g., made of crystalline silicon), which can be used as source/drain regions for P-type transistors (e.g., P-type MOSFETs (PMOSFETs)), may be in-situ doped with a P-type dopant during the epitaxial growth process. The P-type dopant may be, for example, but not limited to, boron (Br), aluminum (Al), gallium (Ga), indium (In), boron fluoride (BF₂), or combinations thereof. In some embodiments, the source/drain features 13 (e.g., made of crystalline silicon), which can be used as source/drain regions for N-type transistors (e.g., N-type MOSFETs (NMOSFETs)), may be in-situ doped with an N-type dopant during the epitaxial growth process. The N-type dopant may be, for example, but not limited to, phosphorus (P), nitrogen (N), arsenic (As), antimony (Sb), or combinations thereof. In some embodiments, each of the source/drain features 13 may include a first epitaxial layer 131, a second epitaxial layer 132, and a third epitaxial layer 133 that are sequentially formed in the source/drain recesses. In some embodiments, two adjacent ones of the source/drain features 13 are separated from each other by a corresponding one of the gate structures 11.

In some embodiments, the semiconductor workpiece 1 may further include a plurality of isolation structures (not shown) to permit the fin portions 102 of the semiconductor substrate 10 to be spaced apart from one another. In some embodiments, the isolation structures may be, for example, but not limited to, shallow trench isolation (STI) structures, deep trench isolation (DTI) structures, or other suitable isolation structures. In some embodiments, the isolation structures are the STI structures, and the isolation structures may be formed by forming a plurality of shallow trenches (not shown) in the semiconductor substrate 10, and filling the shallow trenches with a dielectric material. In some embodiments, the dielectric material for forming the isolation structures may be a low-k dielectric material. In some embodiments, the low-k dielectric material may include, for example, but not limited to, silicon oxide, silicon nitride, silicon oxynitride, silicon carbonitride, silicon oxycarbide, silicon oxycarbonitride, silicon carbide, and combinations thereof. Other suitable materials for forming the isolation structures are within the contemplated scope of the present disclosure.

Referring to FIG. 1 and the example illustrated in FIG. 3, the method 100A then proceeds to step S02, where a first dielectric layer 14 is formed on the structure shown in FIG. 2. Step S02 may be performed by a suitable deposition process, for example, but not limited to, CVD, PECVD, ALD, PEALD, or other suitable deposition processes. The first dielectric layer 14 is formed to cover the gate structures 11, the gate spacers 12, the source/drain features 13, and other structures. The first dielectric layer 14 may be made of a dielectric material, for example, but not limited to, silicon oxide, silicon nitride, silicon oxynitride, silicon carbonitride, silicon oxycarbide, silicon oxycarbonitride, or combinations thereof. Other suitable dielectric materials for forming the first dielectric layer 14 are within the contemplated scope of the present disclosure.

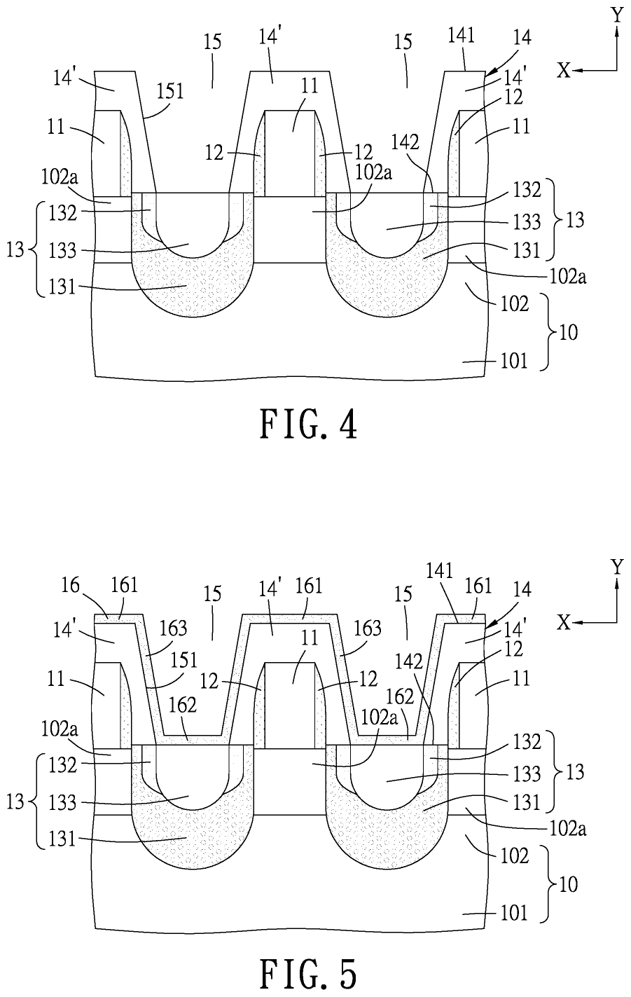

Referring to FIG. 1 and the example illustrated in FIG. 4, the method 100A then proceeds to step S03, where a plurality of contact openings 15 are formed. Step S03 may be performed by patterning the first dielectric layer 14 using a photolithography technique. The photolithography technique may include, for example, but not limited to, coating a photoresist (not shown) on the first dielectric layer 14, soft-baking the photoresist, exposing the photoresist through a photomask (not shown), post-exposure baking the photoresist, developing the photoresist, hard-baking the photoresist to form a patterned photoresist on the first dielectric layer 14, and etching portions of the first dielectric layer 14 exposed from the patterned photoresist, so as to form the contact openings 15. The exposed portions of the first dielectric layer 14 may be etched by a suitable etching process, for example, but not limited to, dry etching, wet etching, other suitable etching processes, or combinations thereof. After this step, the first dielectric layer 14 is formed with a plurality of first dielectric portions 14′ that are spaced apart from one another, and the source/drain features 13 are partially exposed from the contact openings 15, respectively. Each of the contact openings 15 is defined by an opening-defining wall 151 which extends from a top surface 141 of the first dielectric layer 14 to a bottom surface 142 of the first dielectric layer 14. In some embodiments, each of the contact openings 15 has a dimension in a first direction (X) parallel to the top surface 141 of the first dielectric layer 14. The dimension of each of the contact openings 15 decreases gradually in a second direction (Y) (i.e., a direction from the top surface 141 of the first dielectric layer 14 to the bottom surface 142 of the first dielectric layer 14) transverse to the first direction (X).

In some embodiments, after formation of the contact openings 15, a plurality of contact portions (not shown) may be formed on exposed portions of the source/drain features 13, respectively. Each of the contact portions may be a metal silicide, for example, but not limited to, titanium silicide, tantalum silicide, cobalt silicide, or combinations thereof. Other suitable materials for forming the contact portions are within the contemplated scope of the present disclosure. In some embodiments, each of the contact portions may have a thickness ranging from about 0 nm to about 4 nm.

Referring to FIG. 1 and the example illustrated in FIG. 5, the method 100A then proceeds to step S04, where an isolation material layer 16 is conformally formed on the structure shown in FIG. 4. The isolation material layer 16 is conformally formed to cover the first dielectric layer 14 and an exposed portion of each of the source/drain features 13. Step S04 may be performed by a suitable deposition process, for example, but not limited to, ALD, PECVD, PEALD, or other suitable deposition processes. In some embodiments, the deposition process may be performed using, a precursor gas (for example, but not limited to, silane (SiH₄) gas or other suitable precursor gases), a source gas (for example, but not limited to, nitrogen (N₂) gas, ammonia (NH₃) gas, or other suitable source gases), and a carrier gas (for example, but not limited to, hydrogen (H₂) or other suitable carrier gases). In some embodiments, the source gas for performing the deposition process may have a volumetric flow rate ranging from about 3 slm (standard liter per minute) to about 19 slm. In some embodiments, the carrier gas for performing the deposition process may have a flow rate ranging from about 5 sccm (standard cubic centimeter per minute) to about 10 sccm. The isolation material layer 16 may include, for example, but not limited to, silicon nitride, aluminum oxide, silicon carbonitride, low-k material, or combinations thereof. Other suitable materials for forming the isolation material layer 16 are within the contemplated scope of the present disclosure. In some embodiments, the isolation material layer 16 may include a plurality of upper portions 161, a plurality of lower portions 162, and a plurality of interconnecting portions 163. The upper portions 161 of the isolation material layer 16 are disposed on the top surface of the first dielectric layer 14. Each of the lower portions 162 of the isolation material layer 16 is disposed on the exposed portion of a corresponding one of the source/drain features 13. Each of the interconnecting portions 163 connects a corresponding one of the upper portions 161 and a corresponding one of the lower portions 162, and laterally covers a corresponding one of the first dielectric portions 14′. That is, each of the interconnecting portions 163 of the isolation material layer 16 is disposed on the opening-defining wall 151 of a corresponding one of the contact openings 15. In some embodiments, when the contact portions are formed to be respectively disposed on the exposed portions of the source/drain features 13, a distance between a lower end surface of each of the interconnecting portions 163 and a top surface of the exposed portion of a corresponding one of the source/drain features 13 may range from about 0 nm to about 4 nm (i.e., the thickness of the contact portions).

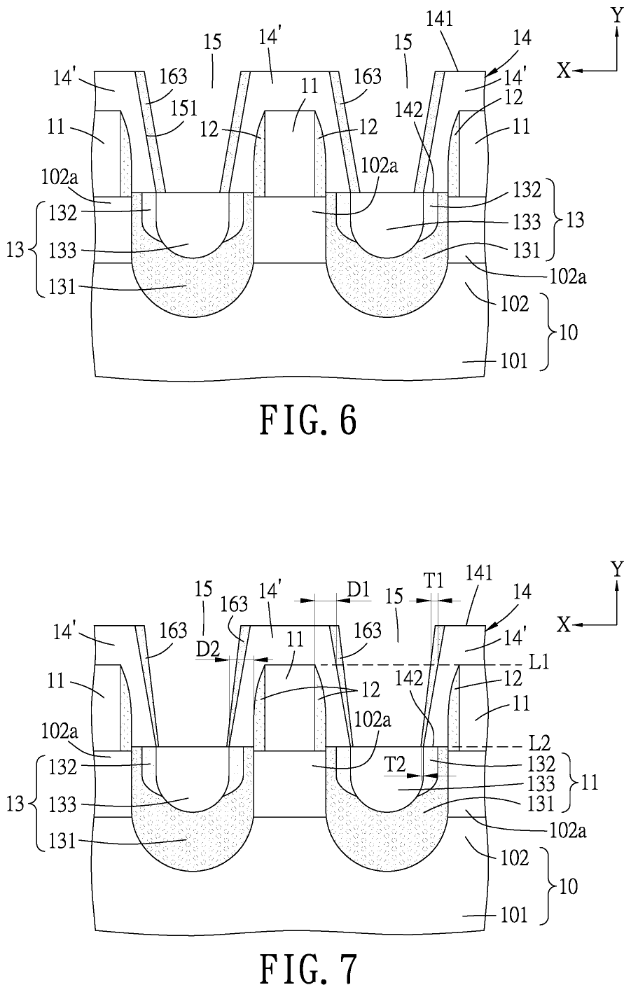

Referring to FIG. 1 and the example illustrated in FIG. 6, the method 100A then proceeds to step S05, where the isolation material layer 16 is partially removed. In this step, the upper portions 161 and the lower portions 162 (see FIG. 5) of the isolation material layer 16 are fully removed. Step S05 may be performed by a suitable etching process, for example, but not limited to, an anisotropic dry etching process or other suitable etching processes.

Referring to FIG. 1 and the example illustrated in FIG. 7, the method 100A then proceeds to step S06, where the interconnecting portions 163 are partially removed, so that each of the interconnecting portions 163 has a non-conformal configuration with a thickness decreasing gradually from the top surface 141 of the first dielectric layer 14 to the bottom surface 142 of the first dielectric layer 14 in the second direction (Y). Step S06 may be performed by a suitable etching process, for example, but not limited to, an anisotropic etching process, an isotropic etching process, or a combination thereof. In some embodiments, a difference between a first thickness (T1) of the interconnecting portion 163 at a first level (L1) identical to a top surface of the gate structure 11 and a second thickness (T2) of the interconnecting portion 163 at a second level (L2) identical to the top surface of the exposed portion of the source/drain feature 13 may range from about 3 nm to about 7 nm. When this difference is smaller than about 3 nm, each of conductive features 17 (which will be described hereinafter with reference to FIG. 9) to be formed may not have an increased contact area that is in contact with a corresponding one of the source/drain features 13, which is not conducive to reducing a contact resistance therebetween and to further enhancing device performance of the semiconductor device 200A. In some embodiments, the difference between the first thickness (T1) and the second thickness (T2) of the interconnecting portion 163 may range from about 4 nm to about 7 nm. In some embodiments, the first thickness (T1) of the interconnecting portion 163 may range from about 3 nm to about 7 nm, and the second thickness (T1) of the interconnecting portion 163 may range from about 0 nm to about 3 nm. In some embodiments, a distance between the first level (L1) and the second level (L2) may range from about 22 nm to about 28 nm. In some embodiments, a first distance (D1) between the interconnecting portion 163 and an adjacent one of the gate structures 11 at the first level (L1) may range from about 3 nm to about 8 nm. If the first distance (D1) is smaller than about 3 nm, the adjacent one of the gate structures 11 may be in direct contact with an adjacent one of the conductive features 17, resulting in an open circuit of the semiconductor device 200A. In some embodiments, a second distance (D2) between the interconnecting portion 163 and the adjacent one of the gate structures 11 at the second level (L2) may range from about 7 nm to about 12 nm.

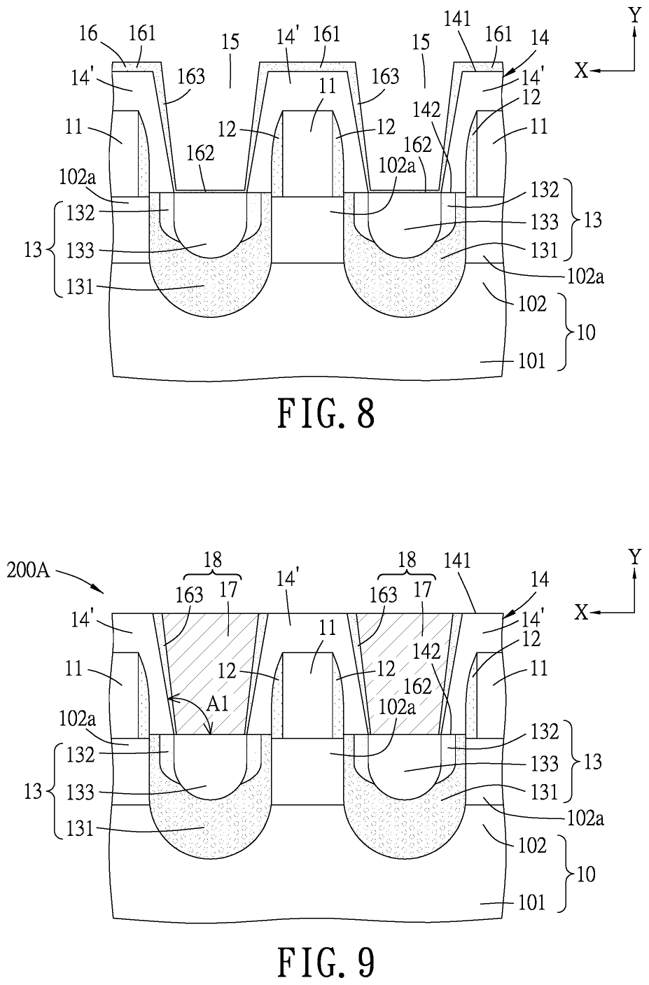

In some embodiments, as shown in FIG. 8, the non-conformal configuration of the interconnecting portions 163 shown in FIG. 7 may be directly obtained by modifying process parameters of the deposition process for forming the isolation material layer 16 (i.e., step S04). For example, when the isolation material layer 16 is formed by ALD, the process parameters (for example, but not limited to, a plasma power, a flow rate of plasma source gas, a deposition time period, or other parameters) of the ALD may be modified to obtain the isolation material layer 16, where each of the interconnecting portions 163 has the non-conformal configuration. In this case, the deposition process for forming the isolation material layer 16 may be performed in the absence of any carrier gas (e.g., hydrogen (H₂)). After formation of the isolation material layer 16, the upper portions 161 and the lower portions 162 are removed (i.e., step S05). In some embodiments, after the upper portions 161 and the lower portions 162 of the isolation material layer 16 of the structure shown in FIG. 8 are removed, the interconnecting portions 163 thus formed may be further trimmed by a suitable etching process (for example, but not limited to, an anisotropic dry etching process, an isotropic etching process, or a combination thereof), if necessary.

Referring to FIG. 1 and the example illustrated in FIG. 9, the method 100A then proceeds to step S07, where a plurality of the conductive features 17 are formed. The conductive features 17 are formed on the exposed portions of the source/drain features 13, respectively. Step S07 may include sub-steps (i) and (ii) described hereinafter.

In sub-step (i), a conductive layer (not shown) for forming the conductive features 17 is formed on the structure shown in FIG. 7. The conductive layer may be made of, for example, but not limited to, tungsten (W), cobalt (Co), ruthenium (Ru), molybdenum (Mo), or combinations thereof. Other suitable materials for forming the conductive features 17 are within the contemplated scope of the present disclosure. The conductive layer may be formed by a suitable deposition process, for example, but not limited to, CVD, PVD, ALD, or other suitable deposition processes.

In sub-step (ii), a planarization process (e.g., a chemical mechanical planarization (CMP) process or other suitable planarization processes) is performed to remove an excess portion of the conductive layer until the top surface 141 of the first dielectric layer 14 is exposed, so as to obtain the conductive features 17.

After this step, the semiconductor device 200A is obtained. In some embodiments, each of the conductive features 17 is laterally covered by a corresponding one pair of the interconnecting portions 163, and may cooperate with the corresponding one pair of the interconnecting portions 163 to serve as a contact via 18 (i.e., the semiconductor device 200A has a plurality of the contact vias 18). Each of the interconnecting portions 163 having the non-conformal configuration serves as a contact isolation layer. In some embodiments, each of the contact vias 18 is formed with a tapered configuration. In some embodiments, each of the contact vias 18 has an inverted trapezoid-shaped cross-section taken in the second direction (Y). In some embodiments, each of the contact vias 18 may have an aspect ratio ranging from about 4.5 to about 5.5. In some embodiments, an included angle (A1) between a bottom surface of the contact via 18 and a side surface of the contact via 18 may be greater than about 90 degrees and up to about 115 degrees.

In some embodiments, after formation of the semiconductor device 200A, an etch stop layer (not shown), a second dielectric layer (not shown), and a plurality of contact features (not shown) may be sequentially formed on the semiconductor device 200A. The etch stop layer may be formed on the first dielectric layer 14 and the contact vias 18. The etch stop layer may include, for example, but not limited to, metal nitride, metal oxide, metal carbide, silicon nitride, silicon oxide, silicon carbide, or combinations thereof. Other suitable materials for forming the etch stop layer are within the contemplated scope of the present disclosure. The etch stop layer may be formed by a suitable deposition process, for example, but not limited to, CVD, PECVD, ALD, spin-on coating, electroless plating, or other suitable deposition processes. The second dielectric layer may be formed on the etch stop layer opposite to the first dielectric layer 14. The material and process for forming the second dielectric layer may be the same as or similar to those for forming the first dielectric layer 14, and thus details thereof are omitted for the sake of brevity. After formation of the second dielectric layer, the etch stop layer and the second dielectric layer are partially etched to form a plurality of openings (not shown), and each of the openings penetrates the second dielectric layer and the etch stop layer. After formation of the openings, a contact layer for forming the contact features is formed on the second dielectric layer and fills the openings, followed by removing an excess portion of the contact layer, so as to form the contact features. The contact layer may include, for example, but not limited to, tungsten or other suitable materials. The contact layer may be formed by a suitable deposition process, for example, but not limited to, CVD, ALD, or other suitable deposition processes. Each of the contact features is disposed on and electrically connected to a corresponding one of the conductive features 17 or a corresponding one of the gate structures 11.

In this disclosure, in a semiconductor device, by forming a contact isolation layer that is disposed between a gate structure and a conductive feature and that has a non-conformal configuration, the gate structure and the conductive feature may be effectively isolated from each other through the contact isolation layer, and a contact area of the conductive feature in direct contact with a source/drain feature may be increased, which is conducive to preventing an open circuit from being formed between the gate structure and the conductive feature, to reducing a contact resistance (e.g., by an amount ranging from about 0.1 kilo ohm (kΩ) to about 0.3 (kΩ) between the conductive feature and the source/drain feature, and to further improving device performance of the semiconductor device.

In accordance with some embodiments of the present disclosure, a semiconductor device includes a semiconductor substrate, a gate structure, a pair of source/drain features, a dielectric layer, and a contact via. The gate structure is disposed on the semiconductor substrate. The source/drain features are disposed at opposite sides of the gate structure. The dielectric layer is disposed on the semiconductor substrate. The contact via is disposed in the dielectric layer and on a corresponding one of the source/drain features. The contact via includes a conductive feature and an isolation layer laterally covering the conductive feature so as to isolate the conductive feature from the gate structure, and has a thickness decreasing gradually in a Y direction from a top surface of the dielectric layer to a bottom surface of the dielectric layer.

In accordance with some embodiments of the present disclosure, a difference between a first thickness of the isolation layer at a first level identical to a top surface of the gate structure and a second thickness of the isolation layer at a second level identical to a top surface of the corresponding one of the source/drain features ranges from about 3 nm to about 7 nm.

In accordance with some embodiments of the present disclosure, the contact via has a dimension in an X direction transverse to the Y direction. The dimension decreases gradually in the Y direction.

In accordance with some embodiments of the present disclosure, the contact via has an inverted trapezoid-shaped cross-section in the Y direction.

In accordance with some embodiments of the present disclosure, the contact via has an included angle between a side surface of the contact via and a bottom surface of the contact via. The included angle is greater than about 90 degrees and up to about 115 degrees.

In accordance with some embodiments of the present disclosure, the contact via has an aspect ratio ranging from about 4.5 to about 5.5.

In accordance with some embodiments of the present disclosure, a distance between the isolation layer and the gate structure at the first level ranges from about 3 nm to about 8 nm.

In accordance with some embodiments of the present disclosure, a distance between the isolation layer and the gate structure at the second level ranges from about 7 nm to about 12 nm.

In accordance with some embodiments of the present disclosure, a method for manufacturing a semiconductor device includes: forming a dielectric layer on a semiconductor structure which includes a gate structure and a pair of source/drain features disposed at opposite sides of the gate structure; patterning the dielectric layer to form an opening which exposes a corresponding one of the source/drain features; conformally forming an isolation material layer on the patterned dielectric layer to partially fill the opening, the isolation material layer including an upper portion disposed on a top surface of the patterned dielectric layer, a lower portion disposed on the corresponding one of the source/drain features, and an interconnecting portion connecting the upper portion and the lower portion; removing the upper portion and the lower portion of the isolation material layer; and partially removing the interconnecting portion, such that the interconnecting portion has a thickness decreasing gradually in a Y direction from the top surface of the patterned dielectric layer to a bottom surface of the patterned dielectric layer.

In accordance with some embodiments of the present disclosure, the interconnecting portion is partially removed by an anisotropic etching process, an isotropic etching process, or a combination thereof.

In accordance with some embodiments of the present disclosure, the opening is formed to have a dimension that decreases gradually in the Y direction.

In accordance with some embodiments of the present disclosure, the isolation material layer is conformally formed by plasma deposition.

In accordance with some embodiments of the present disclosure, the plasma deposition is atomic layer deposition (ALD), plasma-enhanced atomic layer deposition (PEALD), or plasma-enhanced chemical vapor deposition (PECVD).

In accordance with some embodiments of the present disclosure, the plasma deposition is conducted using a source gas that includes nitrogen (N₂) gas, ammonia (NH₃) gas, or a combination thereof, and that has a volumetric flow rate ranging from about 3 slm to about 19 slm.

In accordance with some embodiments of the present disclosure, the plasma deposition is conducted using a carrier gas that includes hydrogen (H₂) gas and that has a flow rate ranging from about 5 sccm to about 10 sccm.

In accordance with some embodiments of the present disclosure, the method for manufacturing a semiconductor device further includes, after partial removal of the interconnecting portion, forming a conductive feature to fill the opening.

In accordance with some embodiments of the present disclosure, a method for manufacturing a semiconductor device includes: forming a semiconductor structure on a semiconductor substrate, the semiconductor structure including a gate structure and a pair of source/drain features disposed at opposite sides of the gate structure; forming a dielectric layer on the semiconductor structure; patterning the dielectric layer to form an opening which exposes a corresponding one of the source/drain features; non-conformally forming an isolation material layer on the patterned dielectric layer to partially fill the opening, such that the isolation material layer includes an upper portion disposed on a top surface of the patterned dielectric layer, a lower portion disposed on the corresponding one of the source/drain features, and an interconnecting portion connecting the upper portion and the lower portion, and such that the interconnecting portion has a thickness decreasing gradually in a Y direction from the top surface of the patterned dielectric layer to a bottom surface of the patterned dielectric layer; and removing the upper portion and the lower portion of the isolation material layer.

In accordance with some embodiments of the present disclosure, the isolation material layer is formed by a deposition process conducted in the absence of a carrier gas.

In accordance with some embodiments of the present disclosure, the carrier gas includes hydrogen gas.

In accordance with some embodiments of the present disclosure, the method for manufacturing a semiconductor device further includes, after removing the upper portion and the lower portion of the isolation material layer, trimming the interconnecting portion using an anisotropic etching process, an isotropic etching process, or a combination thereof.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a semiconductor substrate;
a gate structure disposed on the semiconductor substrate;
a pair of source/drain features disposed at opposite sides of the gate structure;
a dielectric layer disposed on the semiconductor substrate; and
a contact via disposed in the dielectric layer and on a corresponding one of the source/drain features, the contact via including a conductive feature and an isolation layer laterally covering the conductive feature so as to isolate the conductive feature from the gate structure, and having a thickness decreasing gradually in a Y direction from a top surface of the dielectric layer to a bottom surface of the dielectric layer.

2. The semiconductor device as claimed in claim 1, wherein a difference between a first thickness of the isolation layer at a first level identical to a top surface of the gate structure and a second thickness of the isolation layer at a second level identical to a top surface of the corresponding one of the source/drain features ranges from 3 nm to 7 nm.

3. The semiconductor device as claimed in claim 1, wherein the contact via has a dimension in an X direction transverse to the Y direction, the dimension decreasing gradually in the Y direction.

4. The semiconductor device as claimed in claim 3, wherein the contact via has an inverted trapezoid-shaped cross-section in the Y direction.

5. The semiconductor device as claimed in claim 4, wherein the contact via has an included angle between a side surface of the contact via and a bottom surface of the contact via, the included angle being greater than 90 degrees and up to 115 degrees.

6. The semiconductor device as claimed in claim 1, wherein the contact via has an aspect ratio ranging from 4.5 to 5.5.

7. The semiconductor device as claimed in claim 2, wherein a distance between the isolation layer and the gate structure at the first level ranges from 3 nm to 8 nm.

8. The semiconductor device as claimed in claim 7, wherein a distance between the isolation layer and the gate structure at the second level ranges from 7 nm to 12 nm.

9. A method for manufacturing a semiconductor device, comprising:
forming a dielectric layer on a semiconductor structure which includes a gate structure and a pair of source/drain features disposed at opposite sides of the gate structure;
patterning the dielectric layer to form an opening which exposes a corresponding one of the source/drain features;
conformally forming an isolation material layer on the patterned dielectric layer to partially fill the opening, the isolation material layer including an upper portion disposed on a top surface of the patterned dielectric layer, a lower portion disposed on the corresponding one of the source/drain features, and an interconnecting portion connecting the upper portion and the lower portion;
removing the upper portion and the lower portion of the isolation material layer; and
partially removing the interconnecting portion, such that the interconnecting portion has a thickness decreasing gradually in a Y direction from the top surface of the patterned dielectric layer to a bottom surface of the patterned dielectric layer.

10. The method as claimed in claim 9, wherein the interconnecting portion is partially removed by an anisotropic etching process, an isotropic etching process, or a combination thereof.

11. The method as claimed in claim 9, wherein the opening is formed to have a dimension that decreases gradually in the Y direction.

12. The method as claimed in claim 9, wherein the isolation material layer is conformally formed by plasma deposition.

13. The method as claimed in claim 12, wherein the plasma deposition is atomic layer deposition, plasma-enhanced atomic layer deposition, or plasma-enhanced chemical vapor deposition.

14. The method as claimed in claim 13, wherein the plasma deposition is conducted using a source gas that includes nitrogen gas, ammonia gas, or a combination thereof, and that has a volumetric flow rate ranging from 3 slm to 19 slm.

15. The method as claimed in claim 13, wherein the plasma deposition is conducted using a carrier gas that includes hydrogen gas and that has a flow rate ranging from 5 sccm to 10 sccm.

16. The method as claimed in claim 9, further comprising, after partial removal of the interconnecting portion, forming a conductive feature to fill the opening.

17. A method for manufacturing a semiconductor device, comprising:
forming a semiconductor structure on a semiconductor substrate, the semiconductor structure including a gate structure and a pair of source/drain features disposed at opposite sides of the gate structure;
forming a dielectric layer on the semiconductor structure;
patterning the dielectric layer to form an opening which exposes a corresponding one of the source/drain features;
non-conformally forming an isolation material layer on the patterned dielectric layer to partially fill the opening, such that the isolation material layer includes an upper portion disposed on a top surface of the patterned dielectric layer, a lower portion disposed on the corresponding one of the source/drain features, and an interconnecting portion connecting the upper portion and the lower portion, and such that the interconnecting portion has a thickness decreasing gradually in a Y direction from the top surface of the patterned dielectric layer to a bottom surface of the patterned dielectric layer; and
removing the upper portion and the lower portion of the isolation material layer.

18. The method as claimed in claim 17, wherein the isolation material layer is formed by a deposition process conducted in the absence of a carrier gas.

19. The method as claimed in claim 18, wherein the carrier gas includes hydrogen gas.

20. The method as claimed in claim 17, further comprising, after removing the upper portion and the lower portion of the isolation material layer, trimming the interconnecting portion using an anisotropic etching process, an isotropic etching process, or a combination thereof.
